(19) United States
(12) Patent Application Publication
(10) Pub. No.: US 2025/0336801 A1
(43) Pub. Date: Oct. 30, 2025

(54) c/o onsemi

(71) Applicant: SEMICONDUCTOR COMPONENTS INDUSTRIES, LLC, Scottsdale, AZ (US)

(72) Inventors: Jeffrey Peter GAMBINO, Gresham, OR (US); Chandrasekharan KOTHANDARAMAN, New York, NY (US); Vincent James MCGAHAY, Poughkeepsie, NY (US)

(73) Assignee: SEMICONDUCTOR COMPONENTS INDUSTRIES, LLC, Scottsdale, AZ (US)

(21) Appl. No.: 18/649,686

(22) Filed: Apr. 29, 2024

(51) Int. Cl. H01L 23/522; H01L 27/146

(52) U.S. Cl. CPC H01L 23/5223; H10D 1/042; H10D 1/714; H10D 1/716; H10F 39/803

(57) ABSTRACT

A 3D metal-insulator-metal (MIM) capacitor for CMOS image sensors. A MIM capacitor includes a dielectric layer defining a plurality of trenches, and a bottom plate of conductive material overlying the dielectric layer and lining sides of the plurality of trenches. The MIM capacitor also includes a capacitor dielectric directly overlying the bottom plate and extending into the plurality of trenches, a top plate of conductive material directly overlying the capacitor dielectric, and a damascene metal layer overlying and directly contacting the top plate.

### BACKGROUND

Image sensors are used in electronic devices such as cellular telephones, cameras, and computers to capture images. In particular, an electronic device is provided with an array of image sensor pixels arranged in a grid pattern. Each image sensor pixel receives incident photons, such as light, and converts the photons into electrical signals. Each image sensor pixel may include a capacitor to store charge representing the sensor signals until the sensor signals are read out by external circuitry.

Metal-insulator-metal (MIM) capacitors are used in a variety of integrated circuit applications. Three-dimensional (3D) MIM capacitors include a top plate overlying a three-dimensional structure. The top plate must be accessible for connecting the 3D MIM capacitor to external circuitry.

### SUMMARY

According to an aspect of the present disclosure, a metal-insulator-metal (MIM) capacitor is provided. The MIM capacitor includes: a dielectric layer defining a plurality of trenches; a bottom plate of conductive material overlying the dielectric layer and lining sides of the plurality of trenches; a capacitor dielectric directly overlying the bottom plate and extending into the plurality of trenches; a top plate of conductive material directly overlying the capacitor dielectric; and a metal layer overlying and directly contacting the top plate.

According to another aspect of the present disclosure, an image sensor is provided. The image sensor includes: a pixel array comprising a plurality of image sensor pixels, wherein each of the image sensor pixels includes: a photodetector; and a metal-insulator-metal (MIM) capacitor connected to the photodetector and configured to store a charge therefrom. The MIM capacitor includes: a dielectric layer; a bottom plate of conductive material overlying the dielectric layer; a capacitor dielectric directly overlying the bottom plate; a top plate of conductive material directly overlying the capacitor dielectric; and an interconnect layer overlying and directly contacting the top plate.

According to another aspect of the present disclosure, a method of forming a metal-insulator-metal (MIM) capacitor is provided. The method includes: forming a dielectric layer defining a plurality of trenches; forming a bottom plate of conductive material overlying the dielectric layer and lining sides of the plurality of trenches; forming a capacitor dielectric directly overlying the bottom plate and extending into the plurality of trenches; forming a top plate of conductive material directly overlying the capacitor dielectric; and forming a damascene metal layer overlying and directly contacting the top plate.

These and other aspects of the present disclosure are disclosed in the following detailed description of the embodiments, the appended claims, and the accompanying figures.

### BRIEF DESCRIPTION OF THE DRAWINGS

For a detailed description of example implementations, reference will now be made to the accompanying drawings in which:

FIG. 1A is a block diagram of an example of an imaging system in accordance with some implementations;

FIG. 1B is a diagram of an example of an imaging system incorporated in a vehicle in accordance with some implementations;

FIG. 2 is a partial schematic and a partial block diagram of an example of an image sensor in accordance with some implementations;

FIG. 3 is a schematic of an example of circuitry in an image sensor pixel in accordance with some implementations;

FIG. 4 shows a fragmentary top view of an integrated circuit device including four first metal-insulator-metal (MIM) capacitors, in accordance with some implementations;

FIG. 5 shows a cross-sectional view of the integrated circuit device of FIG. 4 through plane X-X;

FIG. 6 shows a cross-sectional view of the integrated circuit device of FIG. 4 through plane Y-Y;

FIG. 7A shows a cross-sectional view of the first MIM capacitor, at a first fabrication step;

FIG. 7B shows a cross-sectional view of the first MIM capacitor, at a second fabrication step;

FIG. 7C shows a cross-sectional view of the first MIM capacitor, at a third fabrication step;

FIG. 7D shows a cross-sectional view of the first MIM capacitor, at a fourth fabrication step;

FIG. 7E shows a cross-sectional view of the first MIM capacitor, at a fifth fabrication step;

FIG. 7F shows a cross-sectional view of the first MIM capacitor, at a sixth fabrication step;

FIG. 8A shows a cross-sectional view of a second MIM capacitor, at a first fabrication step;

FIG. 8B shows a cross-sectional view of the second MIM capacitor, at a second fabrication step;

FIG. 8C shows a cross-sectional view of the second MIM capacitor, at a third fabrication step;

FIG. 8D shows a cross-sectional view of the second MIM capacitor, at a fourth fabrication step;

FIG. 8E shows a cross-sectional view of the second MIM capacitor, at a fifth fabrication step;

FIG. 9A shows a cross-sectional view of a third MIM capacitor, at a first fabrication step;

FIG. 9B shows a cross-sectional view of the third MIM capacitor, at a second fabrication step;

FIG. 9C shows a cross-sectional view of the third MIM capacitor, at a third fabrication step;

FIG. 9D shows a cross-sectional view of the third MIM capacitor, at a fourth fabrication step;

FIG. 9E shows a cross-sectional view of the third MIM capacitor, at a fifth fabrication step;

FIG. 10 shows a cross-sectional view of a fourth MIM capacitor having a capacitor dielectric with gaps defining a hole with no solid material therein;

FIG. 11 shows a cross-sectional view of a fifth MIM capacitor having a capacitor dielectric with gaps filled by a metal material;

FIG. 12 shows a cross-sectional view of a sixth MIM capacitor having a capacitor dielectric with gaps filled by material of a passivation layer; and

FIG. 13 is a flow diagram showing steps in a method of forming a metal-insulator-metal (MIM) capacitor, in accordance with the present disclosure.

### DEFINITIONS

Various terms are used to refer to particular system components. Different companies may refer to a component by different names—this document does not intend to distinguish between components that differ in name but not function. In the following discussion and in the claims, the terms “including” and “comprising” are used in an open-ended fashion, and thus should be interpreted to mean “including, but not limited to . . . ” Also, the term “couple” or “couples” is intended to mean either an indirect or direct connection. Thus, if a first device couples to a second device, that connection may be through a direct connection or through an indirect connection via other devices and connections.

Terms defining an elevation, such as “above,” “below,” “upper”, and “lower” shall be locational terms in reference to a direction of light incident upon a pixel array and/or an image pixel. Light entering shall be considered to interact with or pass objects and/or structures that are “above” and “upper” before interacting with or passing objects and/or structures that are “below” or “lower.” Thus, the locational terms may not have any relationship to the direction of the force of gravity.

“A”, “an”, and “the” as used herein refers to both singular and plural referents unless the context clearly dictates otherwise. By way of example, “a processor” programmed to perform various functions refers to one processor programmed to perform each and every function, or more than one processor collectively programmed to perform each of the various functions. To be clear, an initial reference to “a [referent]”, and then a later reference for antecedent basis purposes to “the [referent]”, shall not obviate the fact the recited referent may be plural.

In relation to electrical devices, whether stand alone or as part of an integrated circuit, the terms “input” and “output” refer to electrical connections to the electrical devices, and shall not be read as verbs requiring action. For example, a differential amplifier, such as an operational amplifier, may have a first differential input and a second differential input, and these “inputs” define electrical connections to the operational amplifier, and shall not be read to require inputting signals to the operational amplifier.

“Light” or “color” shall mean visible light ranging between about 380 and 700 nanometers. “Light” or “color” shall also mean light ranging between 700 nanometers to 800 nanometers, and invisible light, such as infrared light ranging between about 800 nanometer and 1 millimeter. “Light” or “color” shall also mean invisible light, such as ultraviolet light ranging between about 100 nanometers to 400 nanometers.

“Controller” shall mean, alone or in combination, individual circuit components, an application specific integrated circuit (ASIC), one or more microcontrollers with controlling software, a reduced-instruction-set computer (RISC) with controlling software, a digital signal processor (DSP), one or more processors with controlling software, a programmable logic device (PLD), a field programmable gate array (FPGA), or a programmable system-on-a-chip (PSOC), configured to read inputs and drive outputs responsive to the inputs.

### DETAILED DESCRIPTION

The following discussion is directed to various implementations of the invention. Although one or more of these implementations may be preferred, the implementations disclosed should not be interpreted, or otherwise used, as limiting the scope of the present disclosure, including the claims. In addition, one skilled in the art will understand that the following description has broad application, and the discussion of any implementation is meant only to be exemplary of that implementation, and not intended to intimate that the scope of the present disclosure, including the claims, is limited to that implementation.

Complementary metal-oxide semiconductor (CMOS) image sensors may require capacitors with high capacitance density (for example, greater than 40 fF/μm2) in each pixel. For small pixel sizes (for example, 2 μm or less), three-dimensional (3D) MIM capacitors may be required to achieve acceptable performance, especially for global shutter and high dynamic range functionality. Such 3D MIM capacitors include a top plate overlying a three-dimensional structure. The top plate must be accessible for connecting the MIM capacitor to the external circuitry. Connection to the top plate of the MIM may be accomplished by landing a via on the top plate. However, such a via connection may be challenging due to the 3D structure of the MIM and may require additional fabrication steps, such as an additional mask.

Various examples are directed to image sensor pixels, image sensors, and related methods. More particularly, at least some examples are directed to image sensor pixels having three-dimensional metal-insulator-metal (3D MIM) capacitors. More particular still, various examples are directed methods and structures for a 3D MIM capacitor having a top plate and with a metal interconnect landing directly on the top plate. The present disclosure provides a variety of several different MIM capacitor designs with various features, and which may be used in image sensor pixels. The MIM capacitors of the present disclosure may enable image sensors with smaller pixel size and/or higher capacitance density. The MIM capacitors of the present disclosure may also eliminate a need for an additional via mask, thereby providing a cost savings over alternative designs that have a via landing on the top plate.

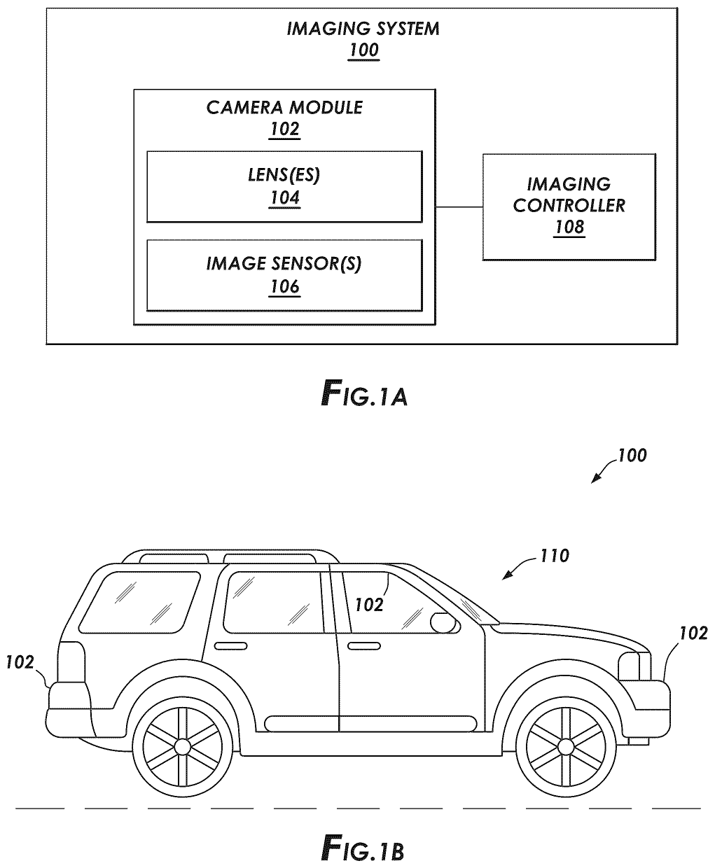

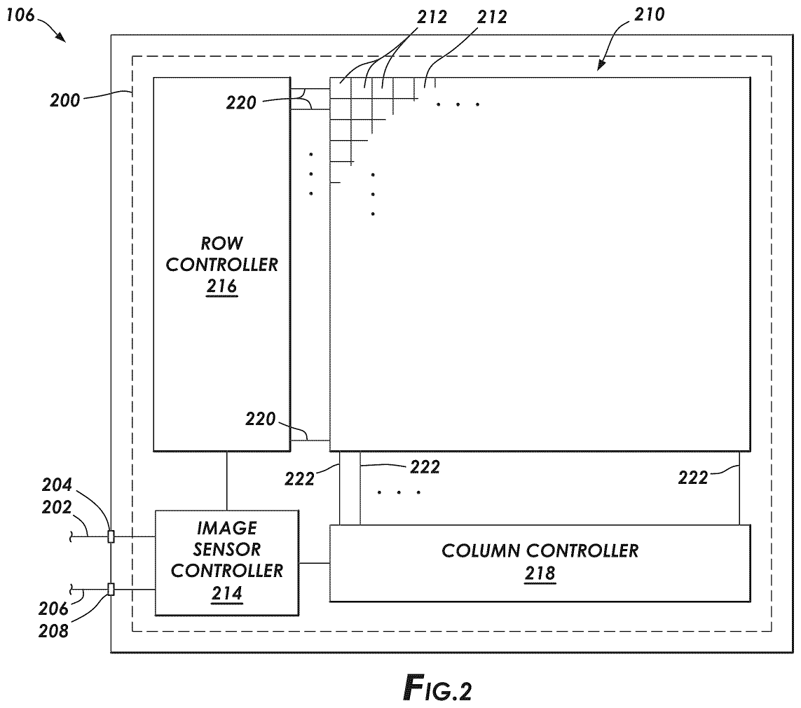

FIG. 1A shows an example of an imaging system 100. In particular, the imaging system 100 may be a portable electronic device such as a camera, a cellular telephone, a tablet computer, a webcam, a video camera, a video surveillance system, or a video gaming system with imaging capabilities. In other cases, the imaging system 100 may be an automotive imaging system. The imaging system 100 illustrated in FIG. 1A includes a camera module 102 that may be used to convert incoming light into digital image data. The camera module 102 may include one or more lenses 104 and one or more corresponding image sensors 106. The lenses 104 may include fixed and/or adjustable lenses. During image capture operations, light from a scene may be focused onto the image sensor 106 by the lenses 104. The image sensor 106 may comprise circuitry for converting analog pixel data into corresponding digital image data to be provided to the imaging controller 108. If desired, the camera module 102 may be provided with an array of lenses 104 and an array of corresponding image sensors 106.

The imaging controller 108 may include one or more integrated circuits. The imaging circuits may include image processing circuits, microprocessors, and storage devices, such as random-access memory, and non-volatile memory. The imaging controller 108 may be implemented using components that are separate from the camera module 102 and/or that form part of the camera module 102, for example, circuits that form part of the image sensor 106. Digital image data captured by the camera module 102 may be processed and stored using the imaging controller 108. Processed image data may, if desired, be provided to external equipment, such as computer, external display, or other device, using wired and/or wireless communications paths coupled to the imaging controller 108.

FIG. 1B shows another example of the imaging system 100. The imaging system 100 illustrated in FIG. 1B comprises an automobile or vehicle 110. The vehicle 110 is illustratively shown as a passenger vehicle, but the imaging system 100 may be other types of vehicles, including commercial vehicles, on-road vehicles, and off-road vehicles. Commercial vehicles may include busses and tractor-trailer vehicles. Off-road vehicles may include tractors and crop harvesting equipment. In the example of FIG. 1B, the vehicle 110 includes a forward-looking cameral module 102 arranged to capture images of scenes in front of the vehicle 110. Such forward-looking camera module 102 can be used for any suitable purpose, such as lane-keeping assist, collision warning systems, distance-pacing cruise-control systems, autonomous driving systems, and proximity detection. The vehicle 110 further comprises a backward-looking camera module 102 arranged to capture images of scenes behind the vehicle 110. Such backward-looking camera module 102 can be used for any suitable purpose, such as collision warning systems, reverse direction video, autonomous driving systems, proximity detection, monitoring position of overtaking vehicles, and backing up. The vehicle 110 may further comprise an inside-looking camera module 102 arranged to capture images of scenes inside the vehicle 110. Such inside-looking camera module 102 can be used for any suitable purpose, such as an in-cabin Driver Monitoring System (DMS) and a Driver plus Occupant Monitoring System (DOMS). The vehicle 110 further comprises a side-looking camera module 102 arranged to capture images of scenes beside the vehicle 110. Such side-looking camera module can be used for any suitable purpose, such as blind-spot monitoring, collision warning systems, autonomous driving systems, monitoring position of overtaking vehicles, lane-change detection, and proximity detection. In situation in which the imaging system 100 is a vehicle, the imaging controller 108 may be a controller of the vehicle 110. The discussion now turns in greater detail to the image sensor 106 of the camera module 102.

FIG. 2 shows an example of the image sensor 106. In particular, FIG. 2 shows that the image sensor 106 may comprise a substrate 200 of semiconductor material (for example, silicon) encapsulated within packaging to create a packaged semiconductor device or packaged semiconductor product. Bond pads or other connection points of the substrate 200 couple to terminals of the image sensor 106, such as the serial communication channel 202 coupled to terminal(s) 204, and capture input 206 coupled to terminal 208. Additional terminals will be present, such as ground, common, or power, but the additional terminals are omitted so as not to unduly complicate the figure. While a single instance of the substrate 200 is shown, in other cases multiple substrates may be combined to form the image sensor 106 to form a multi-chip module.

The image sensor 106 comprises a pixel array 210 containing a plurality of image sensor pixels 212 arranged in rows and columns. Pixel array 210, being one example of an “array of pixels,” may comprise, for example, hundreds or thousands of rows and columns of image sensor pixels 212. Control and readout of the pixel array 210 may be implemented by an image sensor controller 214 coupled to a row controller 216 and a column controller 218. The row controller 216 may receive row addresses from image sensor controller 214 and supply corresponding row control signals to image sensor pixels 212, such as reset, row-select, charge transfer, dual conversion gain, and readout control signals. The row control signals may be communicated over one or more conductors, such as row control paths 220.

Column controller 218 may be coupled to the pixel array 210 by way of one or more conductors, such as column lines 222. Column controllers may sometimes be referred to as column control circuits, readout circuit, or column decoders. Column lines 222 may be used for reading out image signals from image sensor pixels 212 and for supplying bias currents and/or bias voltages to image sensor pixels 212. If desired, during pixel readout operations, a pixel row in the pixel array 210 may be selected using row controller 216 and image signals generated by image sensor pixels 212 in that pixel row can be read out along column lines 222. The column controller 218 may include sample-and-hold circuitry for sampling and temporarily storing image signals read out from pixel array 210, amplifier circuitry, analog-to-digital conversion (ADC) circuitry, bias circuitry, column memory, latch circuitry for selectively enabling or disabling the column circuitry, or other circuitry that is coupled to one or more columns of pixels in the pixel array 210 for operating the image sensor pixels 212 and for reading out image signals from the image sensor pixels 212. ADC circuitry in the column controller 218 may convert analog pixel values received from the pixel array 210 into corresponding digital image data. Column controller 218 may supply digital image data to the image sensor controller 214 and/or the imaging controller 108 (FIG. 1A) over, for example, the serial communication channel 202.

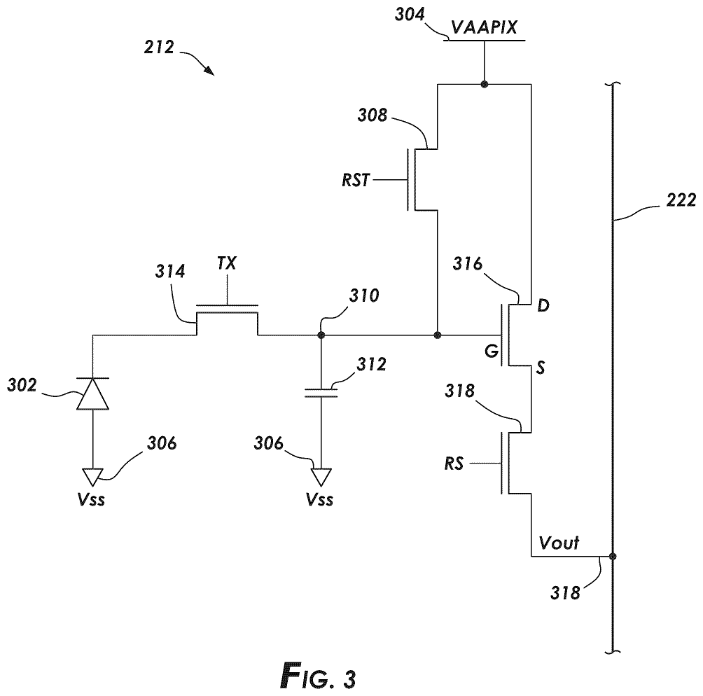

FIG. 3 shows an example of circuitry in one of the image sensor pixels 212. The image sensor pixels 212 may have fewer components, additional components, or different components in different configurations than the one illustrated in FIG. 3. In particular, FIG. 3 shows that each of the image sensor pixels 212 may comprise a photodetector 302 (for example, a photodiode). A positive pixel power supply voltage, such as supply voltage VAAPIX, may be supplied at a positive power supply terminal 304. A ground power supply voltage, such a reference voltage Vss, may be supplied at a ground terminal 306. Incoming light is gathered by the photodetector 302. The photodetector 302 converts the light to electrical charge.

Before an image is acquired, a reset control signal RST may be asserted. The reset control signal RST turns on a reset transistor 308 and resets an intermediate node 310 to a voltage equal or close to the supply voltage VAAPIX. The reset control signal RST may then be de-asserted to turn off the reset transistor 308. After the reset process is complete, a transfer gate control signal TX may be asserted to turn on a transfer transistor 314. A pixel capacitor 312 is connected between the intermediate node 310 and the ground terminal 306. When the transfer transistor 314 is turned on, charge generated by the photodetector 302 in response to incoming light is transferred to the pixel capacitor 312, via the intermediate node 310. The pixel capacitor 312 stores the charge that has been transferred from the photodetector 302 and maintains a voltage on the intermediate node 310 representing a signal indicating the light detection. The signal associated with the charge stored in the pixel capacitor 312 is buffered by a source-follower transistor 316. A row select transistor 318 connects the source-follower transistor 316 to one of the column lines 222.

When it is desired to read out the value of the charge stored in the pixel capacitor 312, a control signal RS is asserted. The read-out value may be, for example, a voltage at the intermediate node 310 that is represented by the signal at the source terminal S of the source-follower transistor 316. When the control signal RS is asserted, the row select transistor 318 is turned on and an output signal Vout that is representative of the magnitude of the charge stored in pixel capacitor 312 is produced on one of the column lines 222. The output signal Vout is one example of a “pixel signal.” When the control signal RS is asserted, one of the column lines 222 can be used to route the output signal Vout from the image sensor pixel 212 to readout circuitry, such as the column controller 218 in FIG. 2.

The pixel capacitor 312 may include a three-dimensional metal-insulator-metal (3D MIM) device to provide a capacitance density required to meet system requirements. In some embodiments, the 3D MIM capacitor may be advantageously used for pixel sizes of 2 μm or less. For example, a 3D MIM capacitor may provide a high capacitance density, such as a capacitance density greater than forty femtofarad per square meter, in each of the image sensor pixels 212.

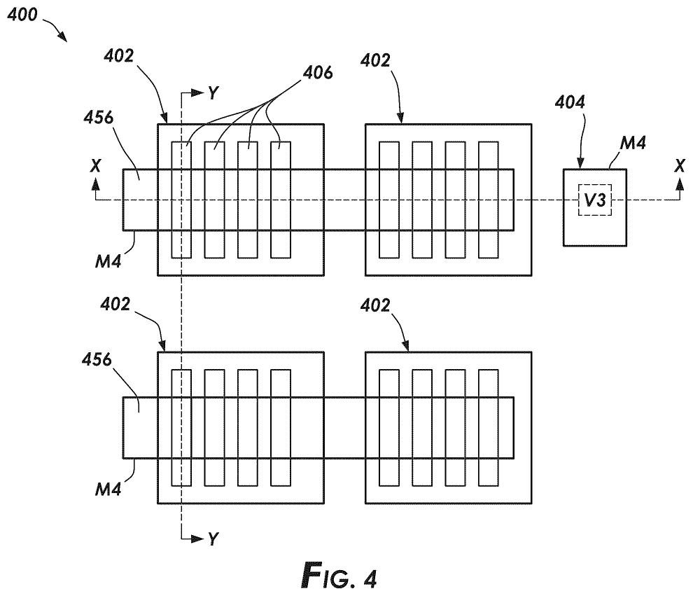

FIG. 4 shows a fragmentary top view of an integrated circuit device 400 including four first metal-insulator-metal (MIM) capacitors 402. The integrated circuit device 400 may implement the image sensor 106, and each of the first MIM capacitors 402 may be used as a pixel capacitor 312 in a corresponding image sensor pixel 212. The integrated circuit device 400 also includes a damascene interconnect structure 404.

Each of the first MIM capacitors 402 includes four trenches 406. Each trench may have a generally rectangular shape. However, the principles of the present disclosure may be applied to MIM capacitor devices having a different number and/or configuration of the trenches 406. The trenches 406 each extend into the plane (that is, in a direction into the drawing sheet of FIG. 4) to define the 3-dimensional (3D) feature of the first MIM capacitors 402.

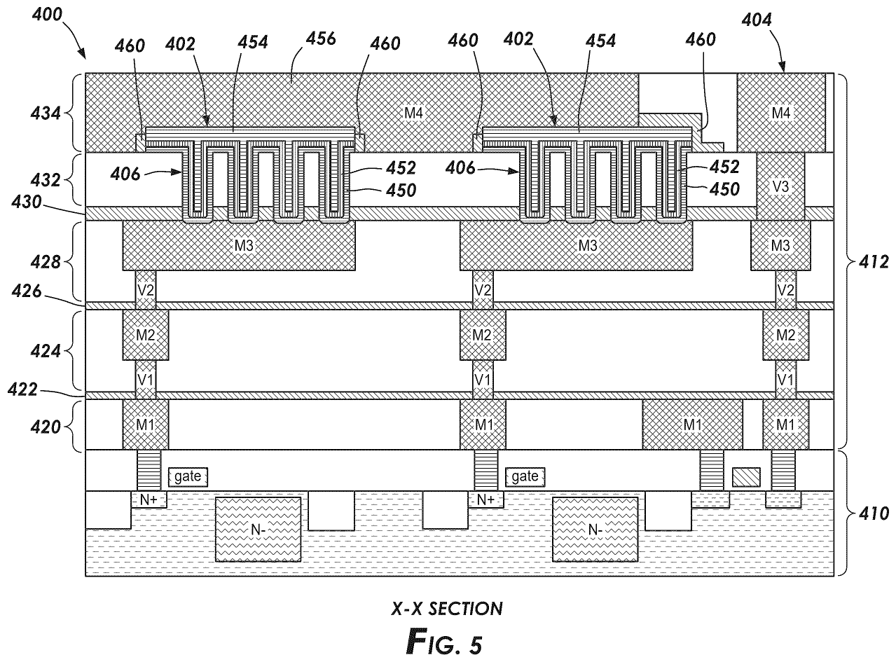

FIG. 5 shows a cross-sectional view of the integrated circuit device 400 of FIG. 4 through plane X-X; and FIG. 6 shows a cross-sectional view of the integrated circuit device of FIG. 4 through plane Y-Y. As shown in FIGS. 5 and 6, the integrated circuit device 400 includes a front end of line (FEOL) portion 410 and a back end of line (BEOL) portion 412 overlying the FEOL portion 410 and attached thereto. The FEOL portion 410 may include one or more semiconductor layers and may implement one or more components of the image sensor pixels 212, such as the photodetector 302 and/or the transistors 308, 314, 316, 318. The BEOL portion 412 includes the first MIM capacitors 402.

As shown, the BEOL portion 412 includes a first dielectric layer 420 that directly overlies the FEOL portion 410. The BEOL portion 412 also includes a first passivation layer 422 directly overlying the first dielectric layer 420. The BEOL portion 412 also includes, subsequently abutting, a second dielectric layer 424, a second passivation layer 426, a third dielectric layer 428, a third passivation layer 430, and a fourth dielectric layer 432. A fifth dielectric layer 434 directly overlies the fourth dielectric layer 432. Each of the dielectric layers 420, 424, 428, 432, 434 may be made of Silicon Dioxide (SiO2). However, other materials may be used. Each of the passivation layers 422, 426, 430 may be made of Silicon Nitride (SiN). However, other materials may be used.

As also shown in FIGS. 5-6, the BEOL portion 412 includes a first metal layer M1 located within a portion of the first dielectric layer 420 and extending therethrough. The BEOL portion 412 also includes a first via layer V1 including a plurality of first vias V1. Each of the first vias V1 extends through a portion of the first passivation layer 422 and into the second dielectric layer 424. A second metal layer M2 also extends through a portion of the second dielectric layer 424. The BEOL portion 412 also includes a second via layer V2 including a plurality of second vias V2. Each of the second vias V2 extends through a portion of the second passivation layer 426 and into the third dielectric layer 428. A third metal layer M3 also extends through a portion of the third dielectric layer 428. The BEOL portion 412 also includes a third via layer V3 including a plurality of third vias V3 Each of the third vias V3 extend through a portion of the third passivation layer 430 and into the fourth dielectric layer 432. A third metal layer M3 also extends through a portion of the fourth dielectric layer 432. A fourth metal layer M4 extends through a portion of the fifth dielectric layer 434. The metal layers M1, M2, M3, M4 may each function to conduct current within a corresponding plane perpendicular to the FEOL portion 410. For example, each of the metal layers M1, M2, M3, M4 may conduct current between two or more different areas of the FEOL portion 410. The vias V1, V2, V3 provide electrical continuity between adjacent ones of the metal layers M1, M2, M3. Each of the vias V1, V2, V3 and the metal layers M1, M2, M3, M4 may be made of metal, such as copper. Furthermore, each of the vias V1, V2, V3 and the metal layers M1, M2, M3, M4 may be formed using a damascene process. Additional structures, such as diffusion barriers, may also be included.

At the damascene interconnect structure 404, all of the vias V1, V2, V3 and all of the metal layers M1, M2, M3, M4 are aligned to provide an electrical connection between the FEOL portion 410 and external circuitry (for example, by a contact pad on the fourth metal layer M4).

As shown in FIGS. 5-6, the fourth dielectric layer 432 defines the four trenches 406 of each of the first MIM capacitors 402. The four trenches 406 may extend parallel to and spaced apart from one-another. For sake of simplicity, only one of the first MIM capacitors 402 is labeled and described in detail. However, each of the first MIM capacitors 402 may have a similar or identical construction.

The first MIM capacitors 402 each include a first bottom plate 450 of conductive material overlying the fourth dielectric layer 432 and lining sides of the trenches 406. The first bottom plate 450 may be made of Titanium Nitride (TiN). However, other materials may be used. A capacitor dielectric 452 is formed as a thin film that directly overlies the first bottom plate 450 and extends into the plurality of trenches 406. The capacitor dielectric 452 may be made of a high-K material, which is a material that has a relatively high dielectric constant (K). Examples of high-K materials that may be used in the capacitor dielectric 452 include: Al2O3, HfO2, ZrO2, HfZrO4, TiO2, Sc2O3 Y2O3, La2O3, Lu2O3, Nb2O5, Ta2O5 and simple mixtures thereof. However, other materials may be used.

The first MIM capacitors 402 each include a top plate 454 of conductive material directly overlying the capacitor dielectric 452. The top plate 454 may be made of Titanium Nitride (TiN). However, other materials may be used. A damascene metal layer 456, which may also be called an interconnect, overlies and directly contacts the top plate 454. The damascene metal layer 456 may include the fourth metal layer M4 of Copper, as shown in FIGS. 5-6. However, the damascene metal layer 456 may be made of another material. The top plate 454 and the first bottom plate 450 of the first MIM capacitors 402, together with the capacitor dielectric 452 may be patterned using a same mask to define a common footprint.

The first MIM capacitors 402 each include a fourth passivation layer 460 that overlies the top plate 454. The fourth passivation layer 460 may be made of Silicon Nitride (SiN). However, other materials may be used. The fourth passivation layer 460 is selectively removed from a portion of the top plate 454 for the damascene metal layer 456 to contact the top plate 454. The fourth passivation layer 460 extends around an edge of the common footprint to provide electrical isolation between the damascene metal layer 456 and the first bottom plate 450. Thus, the fourth passivation layer 460 prevents a short-circuit in the first MIM capacitors 402 that could otherwise occur if the damascene metal layer 456 were to contact both of the top plate 454 and the first bottom plate 450.

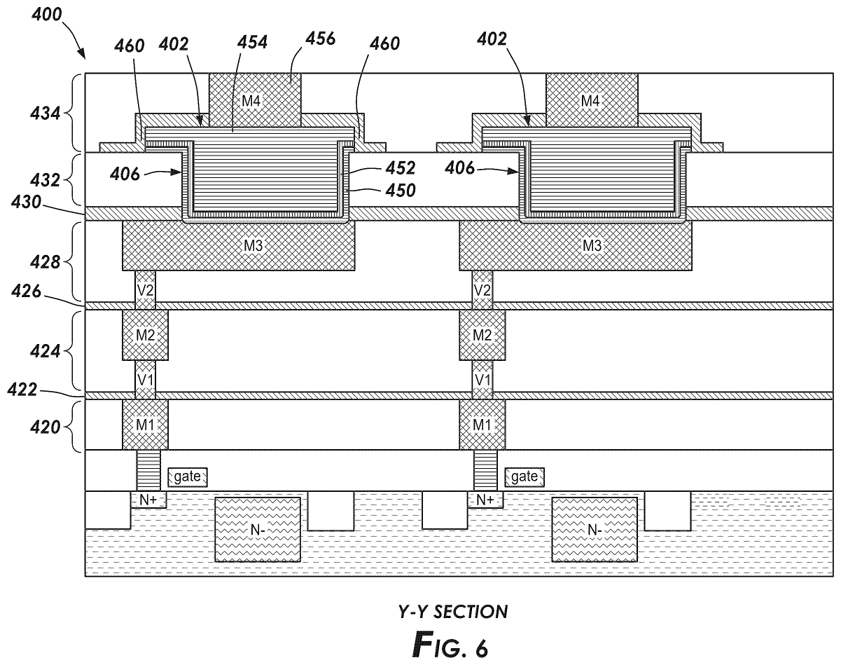

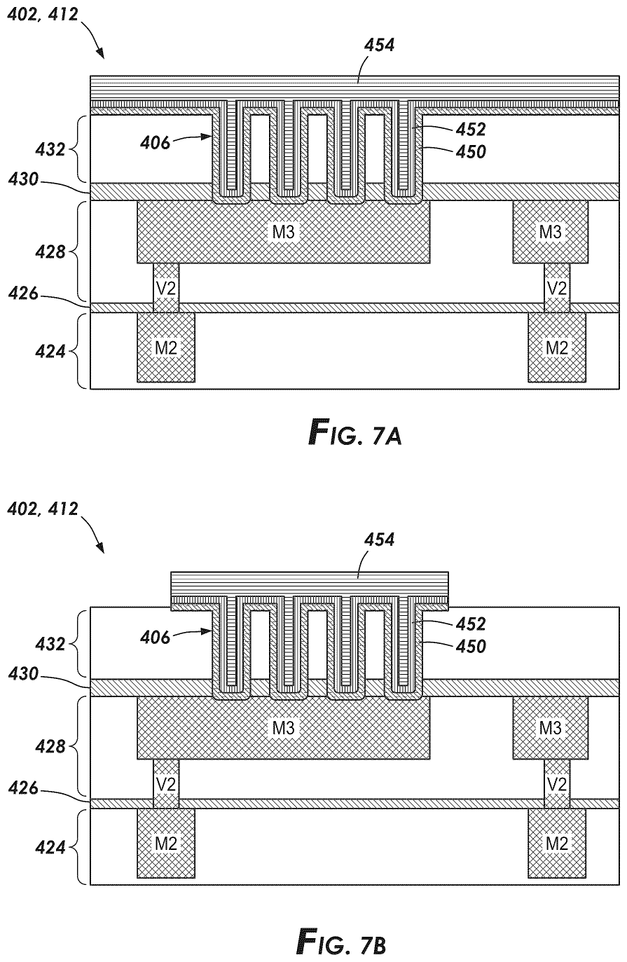

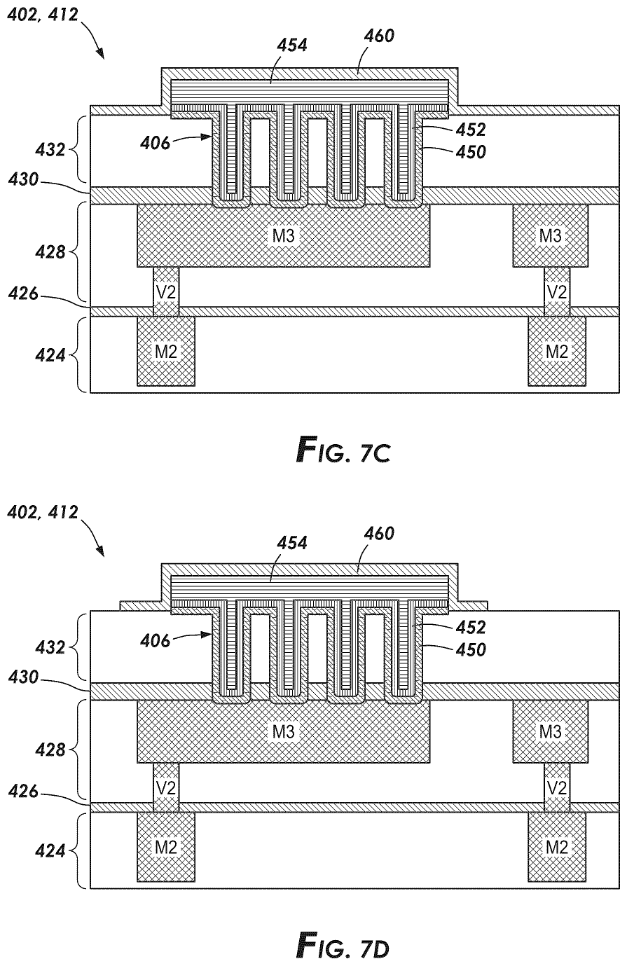

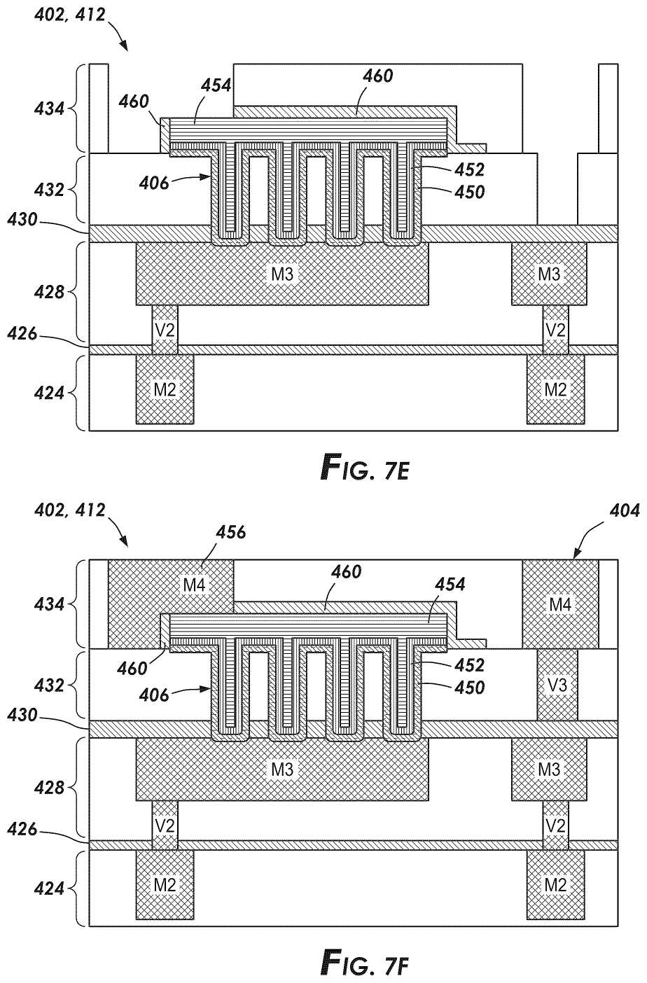

FIG. 7A shows a cross-sectional view of the first MIM capacitor 402, at a first fabrication step. In the first fabrication step of FIG. 7A, the trenches 406 are formed in the fourth dielectric layer 432. Also, the first bottom plate 450, the capacitor dielectric 452, and the top plate 454 are deposited in the trenches 406 and overlying the fourth dielectric layer 432. FIG. 7A also shows the capacitor dielectric 452 of the first MIM capacitor 402 defining a gap extending into each of the trenches 406. The top plate 454 extends into the gaps. In other words, the material of the top plate 454 may be deposited to fill the gaps in the capacitor dielectric 452.

FIG. 7B shows a cross-sectional view of the first MIM capacitor 402, at a second fabrication step. In the second fabrication step of FIG. 7B, the first bottom plate 450, the capacitor dielectric 452, and the top plate 454 of the first MIM capacitor 402 are each patterned using a same mask to define a common footprint. The common footprint includes the first bottom plate 450, the capacitor dielectric 452, and the top plate 454 each having a same size and shape. In other words, and as shown in FIG. 7B, the common footprint includes the first bottom plate 450, the capacitor dielectric 452, and the top plate 454 are stacked in parallel layers and each having peripheral edges that are vertically aligned.

FIG. 7C shows a cross-sectional view of the first MIM capacitor 402, at a third fabrication step. In the third fabrication step, the fourth passivation layer 460 is deposited overlying the common footprint of the first MIM capacitor 402 and extending beyond the common footprint of the first MIM capacitor 402 to directly overlie the fourth dielectric layer 432 in some areas.

FIG. 7D shows a cross-sectional view of the first MIM capacitor 402, at a fourth fabrication step. In the fourth fabrication step, the fourth passivation layer 460 is patterned to expose at least a portion of the fourth dielectric layer 432. Subsequently, the fifth dielectric layer 434 may be deposited over the patterned fourth passivation layer 460. The fifth dielectric layer 434 may extend beyond the common footprint of the first MIM capacitor 402 to directly overlie the fourth dielectric layer 432 in some areas.

FIG. 7E shows a cross-sectional view of the first MIM capacitor 402, at a fifth fabrication step. In the fifth fabrication step, the fifth dielectric layer 434 and a portion of the fourth passivation layer 460 are each patterned, selectively removing a portion thereof for forming the fourth metal layer M4. The fifth fabrication step also includes selectively removing one or more portions of the fourth dielectric layer 432 for forming the third vias V3.

FIG. 7F shows a cross-sectional view of the first MIM capacitor 402, at a sixth fabrication step. In the sixth fabrication step, the third vias V3 and the fourth metal layer M4 are formed by the damascene process. The sixth fabrication step may also be called metallization. In the sixth fabrication step, the fourth metal layer M4 is formed to overlie and directly contact at least a portion of the top plate 454. Also, as shown on FIG. 7F, at least a portion of the fourth passivation layer 460 extends around an edge of the edge of the top plate 454 and the first bottom plate 450 to provide electrical isolation between the fourth metal layer M4 and the first bottom plate 450.

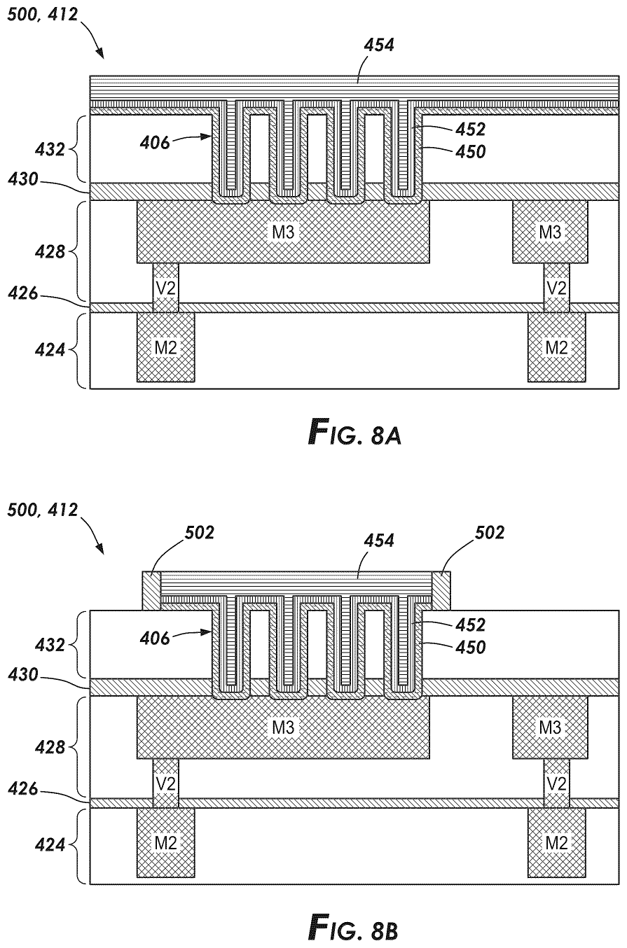

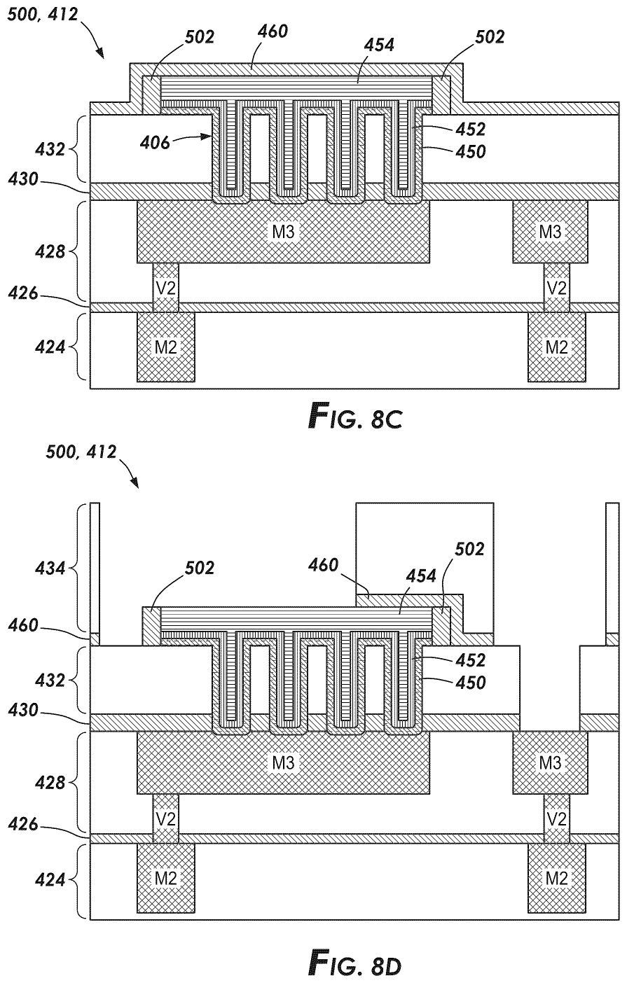

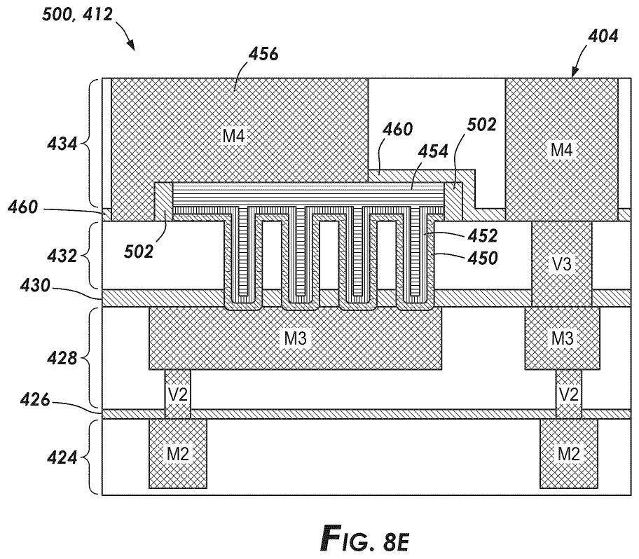

FIG. 8A shows a cross-sectional view of a second MIM capacitor 500, at a first fabrication step. The second MIM capacitor 500 may be similar or identical to the first MIM capacitor 402, except for the differences described herein. The second MIM capacitor 500 may be used as a pixel capacitor 312 in a corresponding image sensor pixel 212. In the first fabrication step shown in FIG. 8A, the trenches 406 are formed in the fourth dielectric layer 432. The first bottom plate 450, the capacitor dielectric 452, and the top plate 454 of the second MIM capacitor 500 are also deposited in the trenches 406 and overlying the fourth dielectric layer 432 in the first fabrication step shown in FIG. 8A.

FIG. 8B shows a cross-sectional view of the second MIM capacitor 500, at a second fabrication step. In the second fabrication step shown in FIG. 8B, the first bottom plate 450, the capacitor dielectric 452, and the top plate 454 of the second MIM capacitor 500 are each patterned using a same mask to define a common footprint. In the second fabrication step shown in FIG. 8B, a spacer 502 of insulating material is also formed to cover an edge of the common footprint to provide electrical isolation between the damascene metal layer 456 and the first bottom plate 450. Thus, the spacer 502 prevents a short-circuit in the second MIM capacitors 500 that could otherwise occur if the damascene metal layer 456 were to contact both of the top plate 454 and the first bottom plate 450. The spacer 502 may be formed of Aluminum Oxide (Al2O3). However, other materials may be used to form the spacer 502.

FIG. 8C shows a cross-sectional view of the second MIM capacitor 500, at a third fabrication step. In the third fabrication step shown in FIG. 8C, the fourth passivation layer 460 is deposited overlying the common footprint of the second MIM capacitor 500 and extending beyond the common footprint of the second MIM capacitor 500 to directly overlie the fourth dielectric layer 432 in some areas.

FIG. 8D shows a cross-sectional view of the second MIM capacitor 500, at a fourth fabrication step. In the fourth fabrication step shown in FIG. 8D, the fifth dielectric layer 434 is deposited. The fourth dielectric layer 432, the fifth dielectric layer 434, and a portion of the fourth passivation layer 460 are each patterned to selectively remove corresponding portions thereof for forming the fourth metal layer M4 and the third vias V3.

FIG. 8E shows a cross-sectional view of the second MIM capacitor 500, at a fifth fabrication step. In the fifth fabrication step shown in FIG. 8E, the third vias V3 and the fourth metal layer M4 are formed by the damascene process. The fifth fabrication step may also be called metallization. In the fifth fabrication step shown in FIG. 8E, the fourth metal layer M4 is formed to overlie and directly contact at least a portion of the top plate 454.

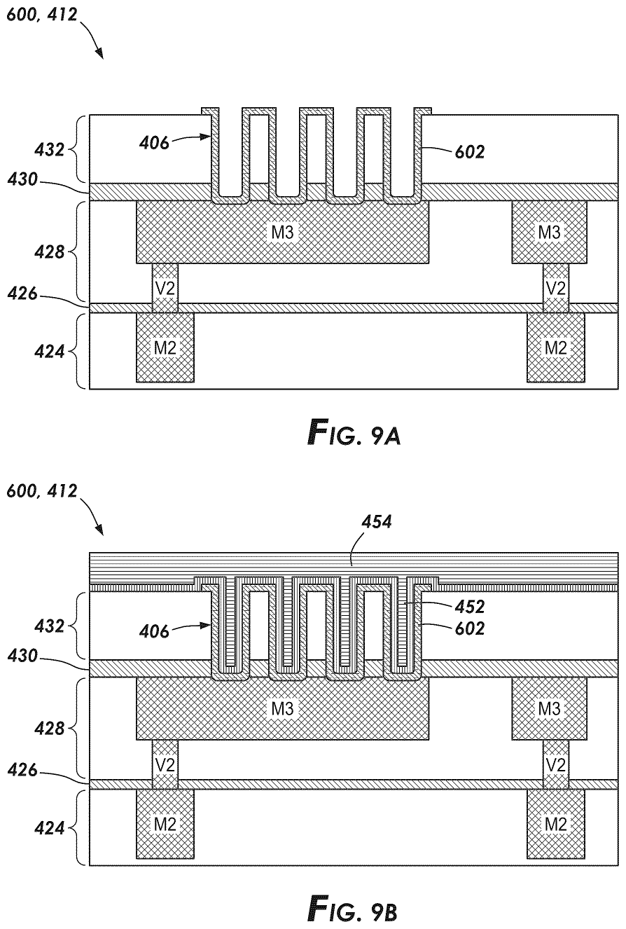

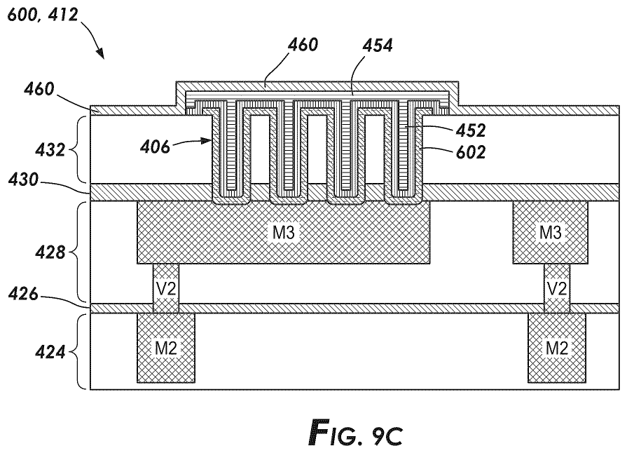

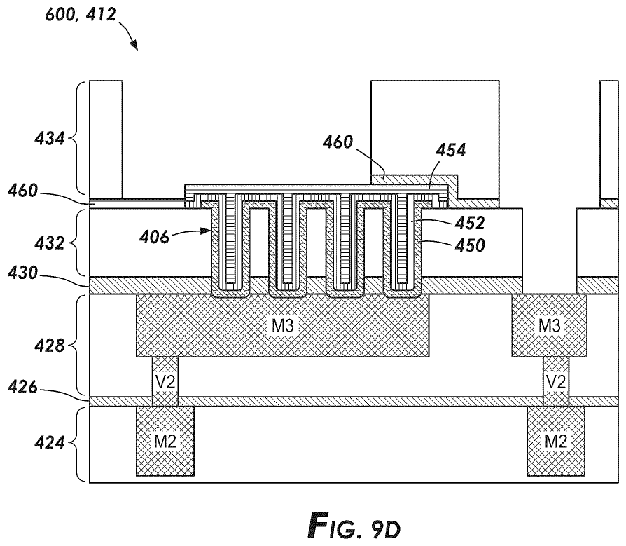

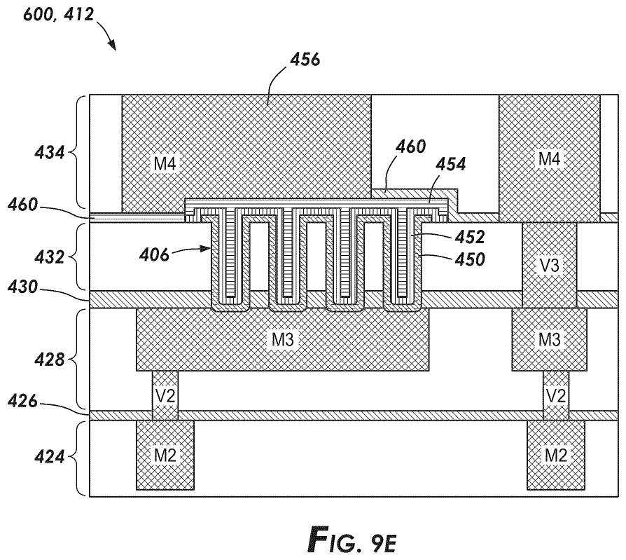

FIG. 9A shows a cross-sectional view of a third MIM capacitor 600, at a first fabrication step. The third MIM capacitor 600 may be similar or identical to the first MIM capacitor 402, except for the differences described herein. The third MIM capacitor 600 may be used as a pixel capacitor 312 in a corresponding image sensor pixel 212. The third MIM capacitor 600 includes a recessed bottom plate 602 in place of the first bottom plate 450 of the first MIM capacitor 402. In the first fabrication step shown in FIG. 9A, the trenches 406 are formed in the fourth dielectric layer 432. The first bottom plate 450 of the third MIM capacitor 600 is also deposited in the trenches 406 and overlying the fourth dielectric layer 432 in the first fabrication step shown in FIG. 9A. The recessed bottom plate 602 of the third MIM capacitor 600 is also patterned, using a first mask, in the first fabrication step shown in FIG. 9A.

FIG. 9B shows a cross-sectional view of the third MIM capacitor 600, at a second fabrication step. In the second fabrication step shown in FIG. 9B, the capacitor dielectric 452 and the top plate 454 are deposited to overlie and extend beyond a periphery of the recessed bottom plate 602. In other words, the capacitor dielectric 452 and the top plate 454 are deposited to protrude beyond or more peripheral edges of the recessed bottom plate 602 in the third MIM capacitor 600.

FIG. 9C shows a cross-sectional view of the third MIM capacitor 600, at a third fabrication step. In the third fabrication step shown in FIG. 9C, the capacitor dielectric 452 and the top plate 454 are each patterned using a second mask to extend beyond a periphery of the recessed bottom plate 602. In the third fabrication step shown in FIG. 9C, the fourth passivation layer 460 is also deposited, overlying the top plate 454 and directly overlying the fourth dielectric layer 432 in some areas.

FIG. 9D shows a cross-sectional view of the third MIM capacitor 600, at a fourth fabrication step. In the fourth fabrication step shown in FIG. 9C, the fifth dielectric layer 434 is deposited. The fourth dielectric layer 432, the fifth dielectric layer 434, and a portion of the fourth passivation layer 460 are each patterned to selectively remove corresponding portions thereof for forming the fourth metal layer M4 and the third vias V3.

FIG. 9E shows a cross-sectional view of the third MIM capacitor 600, at a fifth fabrication step. In the fifth fabrication step shown in FIG. 9E, the third vias V3 and the fourth metal layer M4 are formed by the damascene process. The fifth fabrication shown in FIG. 9E step may also be called metallization. In the fifth fabrication step shown in FIG. 9E, the fourth metal layer M4 is formed to overlie and directly contact at least a portion of the top plate 454. As shown, the fourth metal layer M4 is separated from the recessed bottom plate 602 by a combination of the capacitor dielectric 452, the top plate 454, and the fourth passivation layer 460.

FIG. 10 shows a cross-sectional view of a fourth MIM capacitor 700 having a capacitor dielectric 452 with a gap extending into each of the trenches 406. The gaps each define a hole 702 with no solid material therein. The hole 702 may be filled with a gas, such as air or nitrogen. The fourth MIM capacitor 700 may be similar or identical to the first MIM capacitor 402, except for the differences described herein. The fourth MIM capacitor 700 may be used as a pixel capacitor 312 in a corresponding image sensor pixel 212.

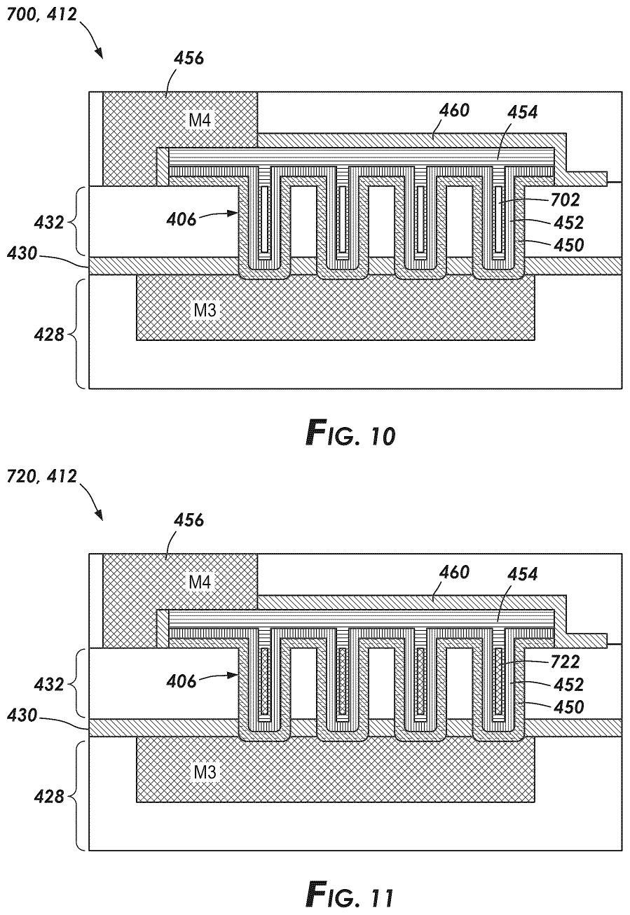

FIG. 11 shows a cross-sectional view of a fifth MIM capacitor 720 having a capacitor dielectric 452 with a gap extending into each of the trenches 406. The gaps each contain a filler 722 of metal material. The metal material may include a same material as the metal layers M1, M2, M3, M4. For example, the filler 722 may include Copper. The fifth MIM capacitor 720 may be similar or identical to the first MIM capacitor 402, except for the differences described herein. The fifth MIM capacitor 720 may be used as a pixel capacitor 312 in a corresponding image sensor pixel 212. The filler 722 may be formed by the damascene process. For example, the filler 722 may be deposited with the third vias V3 and the fourth metal layer M4.

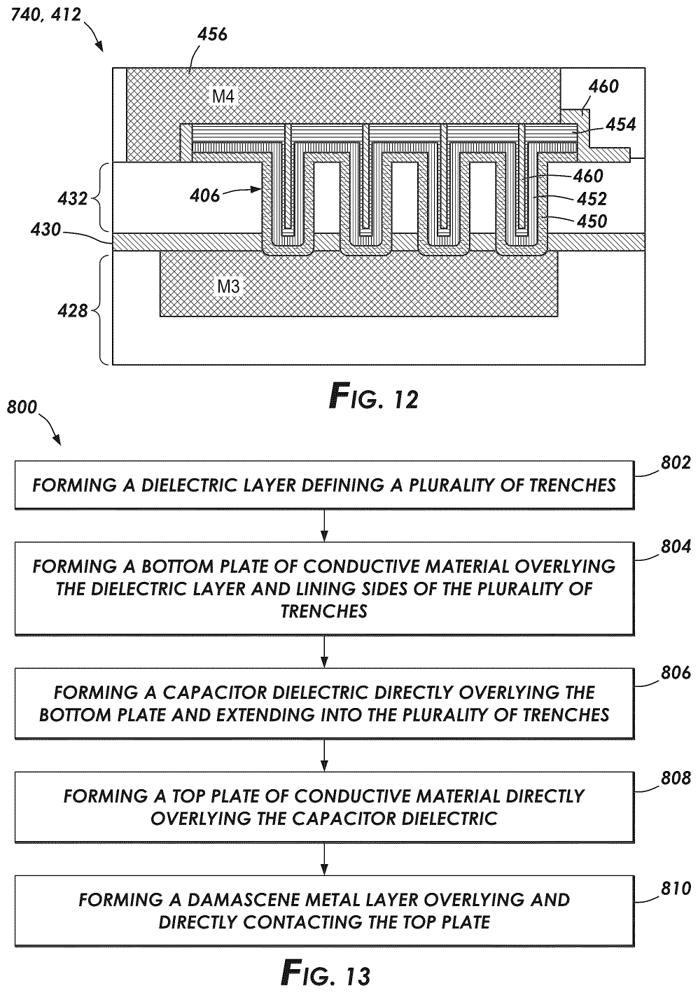

FIG. 12 shows a cross-sectional view of a sixth MIM capacitor 740 having a capacitor dielectric 452 with a gap extending into each of the trenches 406. The fourth passivation layer 460 extends into each of the gaps. In other words, the material of the fourth passivation layer 460 may be deposited to fill at least a portion of the gaps in the capacitor dielectric 452. The sixth MIM capacitor 740 may be similar or identical to the first MIM capacitor 402, except for the differences described herein. The sixth MIM capacitor 740 may be used as a pixel capacitor 312 in a corresponding image sensor pixel 212.

FIG. 13 is a flow diagram showing steps in a method 800 of forming a metal-insulator-metal (MIM) capacitor, in accordance with the present disclosure. For simplicity of explanation, the method 800 is depicted in FIG. 13 and described as a series of operation. However, the operations can occur in various orders and/or concurrently, and/or with other operations not presented and described herein.

The method 800 includes forming a dielectric layer defining a plurality of trenches, at step 802. For example, the fourth dielectric layer 432 may be deposited and patterned to define the trenches 406.

The method 800 also includes forming a bottom plate of conductive material overlying the dielectric layer and lining sides of the plurality of trenches, at step 804. For example, Titanium Nitride (TiN) may be deposited and patterned on top of the fourth dielectric layer 432 and lining the trenches 406 to define the first bottom plate 450.

The method 800 also includes forming a capacitor dielectric directly overlying the bottom plate and extending into the plurality of trenches, at step 806. For example, the high-K material may be deposited and patterned on top of the first bottom plate 450 to define the capacitor dielectric 452.

The method 800 includes forming a top plate of conductive material directly overlying the capacitor dielectric, at step 808. For example, Titanium Nitride (TiN) may be deposited and patterned on top of the capacitor dielectric 452 to define the top plate 454.

The method 800 also includes forming a damascene metal layer overlying and directly contacting the top plate, at step 810. For example, the fourth metal layer M4 may be formed by the damascene process to overlie and directly contact at least a portion of the top plate 454.

In some embodiments, forming the bottom plate and forming the top plate includes patterning the bottom plate and the top plate using a same mask to define a common footprint. For example, the method 800 may be used to form the first MIM capacitors 402 or the second MIM capacitors 500.

In some embodiments, the method 800 further includes forming a passivation layer overlying the top plate. The passivation layer may be selectively removed from at least a portion of the top plate for the damascene metal layer to contact the top plate, and the passivation layer may further extend around an edge of the common footprint to provide electrical isolation between the damascene metal layer and the bottom plate. For example, the method 800 may include depositing and patterning Silicon Nitride (SiN) to form the fourth passivation layer 460 overlying at least a portion of the top plate 454 and extending around an edge of the common footprint of the top plate 454 and the first bottom plate 450 to provide electrical isolation between the fourth metal layer M4 and the first bottom plate 450.

In some embodiments, the method 800 further includes forming a spacer of insulating material covering an edge of the common footprint and configured to provide electrical isolation between the damascene metal layer and the bottom plate. For example, Aluminum Oxide (Al2O3) may be deposited and patterned to form the spacers 502 of the second MIM capacitor 500, covering one or more edges of the common footprint to provide physical separation and electrical isolation between the damascene metal layer 456 and the first bottom plate 450.

In some embodiments, forming the bottom plate includes patterning the bottom plate using a first mask, and forming the capacitor dielectric includes patterning the capacitor dielectric using a second mask to extend beyond a periphery of the bottom plate. For example, the method 800 may be used to form the third MIM capacitor 600 with the recessed bottom plate 602 and with each of the capacitor dielectric 452 and the top plate 454 overlying and protruding beyond a periphery of the recessed bottom plate 602, thereby providing physical separation and electrical isolation between the damascene metal layer 456 and the recessed bottom plate 602.

Many of the electrical connections in the drawings are shown as direct couplings having no intervening devices, but not expressly stated as such in the description above. Nevertheless, this paragraph shall serve as antecedent basis in the claims for referencing any electrical connection as “directly coupled” for electrical connections shown in the drawing with no intervening device(s).

The above discussion is meant to be illustrative of the principles and various implementations of the present invention. Numerous variations and modifications will become apparent to those skilled in the art once the above disclosure is fully appreciated. It is intended that the following claims be interpreted to embrace all such variations and modifications.

What is claimed is:

1. A metal-insulator-metal (MIM) capacitor, comprising:
a dielectric layer defining a plurality of trenches;
a bottom plate of conductive material overlying the dielectric layer and lining sides of the plurality of trenches;
a capacitor dielectric directly overlying the bottom plate and extending into the plurality of trenches;
a top plate of conductive material directly overlying the capacitor dielectric; and
a metal layer overlying and directly contacting the top plate.

2. The MIM capacitor of claim 1, wherein the bottom plate and the top plate have a common footprint.

3. The MIM capacitor of claim 2, further comprising a passivation layer partially overlying the top plate, and
wherein the passivation layer further extends around an edge of the common footprint to provide electrical isolation between the metal layer and the bottom plate.

4. The MIM capacitor of claim 2, further comprising a spacer of insulating material covering an edge of the common footprint.

5. The MIM capacitor of claim 1, wherein the capacitor dielectric extends beyond a periphery of the bottom plate.

6. The MIM capacitor of claim 1, wherein the capacitor dielectric defines a gap within at least one trench of the plurality of trenches, and
wherein the top plate extends into the gap within the at least one trench.

7. The MIM capacitor of claim 1, wherein the capacitor dielectric defines a gap within at least one trench of the plurality of trenches, and
wherein the gap defines a hole with no solid material therein.

8. The MIM capacitor of claim 1, wherein the capacitor dielectric defines a gap within at least one trench of the plurality of trenches, and
wherein the gap is filled by a metal material of the metal layer.

9. The MIM capacitor of claim 1, further comprising a passivation layer partially overlying the top plate,
wherein the capacitor dielectric defines a gap within at least one trench of the plurality of trenches, and
wherein the passivation layer extends into the gap.

10. An image sensor comprising:
a pixel array comprising a plurality of image sensor pixels, wherein each of the image sensor pixels includes:
a photodetector; and
a metal-insulator-metal (MIM) capacitor connected to the photodetector and configured to store a charge therefrom, the MIM capacitor including:
a dielectric layer;
a bottom plate of conductive material overlying the dielectric layer;
a capacitor dielectric directly overlying the bottom plate;
a top plate of conductive material directly overlying the capacitor dielectric; and
an interconnect layer overlying and directly contacting the top plate.

11. The image sensor of claim 10, wherein the bottom plate and the top plate have a common footprint.

12. The image sensor of claim 11, wherein the MIM capacitor further comprises a passivation layer partially overlying the top plate, and
wherein the passivation layer further extends around an edge of the common footprint.

13. The image sensor of claim 11, wherein the MIM capacitor further comprises a spacer of insulating material covering an edge of the common footprint.

14. The image sensor of claim 10, wherein the capacitor dielectric extends beyond a periphery of the bottom plate.

15. A vehicle including the image sensor of claim 10.

16. A method of forming a metal-insulator-metal (MIM) capacitor, comprising:
forming a dielectric layer defining a plurality of trenches;
forming a bottom plate of conductive material overlying the dielectric layer and lining sides of the plurality of trenches;
forming a capacitor dielectric directly overlying the bottom plate and extending into the plurality of trenches;
forming a top plate of conductive material directly overlying the capacitor dielectric; and
forming a damascene metal layer overlying and directly contacting the top plate.

17. The method of claim 16, wherein forming the bottom plate and forming the top plate includes patterning the bottom plate and the top plate using a same mask to define a common footprint.

18. The method of claim 17, further including forming a passivation layer overlying the top plate, wherein the passivation layer is selectively removed from at least a portion of the top plate for the damascene metal layer to contact the top plate, and
wherein the passivation layer further extends around an edge of the common footprint to provide electrical isolation between the damascene metal layer and the bottom plate.

19. The method of claim 17, further including forming a spacer of insulating material covering an edge of the common footprint and configured to provide electrical isolation between the damascene metal layer and the bottom plate.

20. The method of claim 16, wherein forming the bottom plate includes patterning the bottom plate using a first mask, and wherein forming the capacitor dielectric includes patterning the capacitor dielectric using a second mask to extend beyond a periphery of the bottom plate.
